(19) United States
(12) Patent Application Publication
(10) Pub. No.: US 2024/0065044 A1
(43) Pub. Date: Feb. 22, 2024

(54) DISPLAY PANEL AND DISPLAY APPARATUS INCLUDING THE SAME

(71) Applicant: Samsung Display Co., Ltd., Yongin-si (KR)

(72) Inventors: Hyuneok Shin, Yongin-si (KR); Joonyong Park, Yongin-si (KR)

(21) Appl. No.: 18/348,228

(22) Filed: Jul. 6, 2023

(30) Foreign Application Priority Data
Aug. 17, 2022 (KR) 10-2022-0102923

(51) Int. Cl. H10K 59/123; H10K 59/131

(52) U.S. Cl. CPC H10K 59/123; H10K 59/1315; H10K 2102/351

(57) ABSTRACT

A display panel includes: a substrate including a main display area, a component area, and a non-display area; a main pixel electrode in the main display area of the substrate and including a multilayer; a main thin film transistor in the main display area of the substrate and electrically connected to the main pixel electrode; an auxiliary pixel electrode in the component area of the substrate and including a multilayer; an auxiliary thin film transistor in the non-display area of the substrate; and a connection wiring electrically connecting the auxiliary thin film transistor to the auxiliary pixel electrode and having a same structure as the auxiliary pixel.

### CROSS-REFERENCE TO RELATED APPLICATION

The present application claims priority to and the benefit of Korean Patent Application No. 10-2022-0102923, filed on Aug. 17, 2022, in the Korean Intellectual Property Office, the entire disclosure of which is incorporated herein by reference.

### BACKGROUND

### 1. Field

Aspects of one or more embodiments relate to a display panel and a display apparatus including the same.

### 2. Description of the Related Art

A display apparatus may include a display element and electronic elements for controlling electrical signals applied to the display element. Electronic elements may include thin film transistors (TFT), storage capacitors, and a plurality of wirings.

Recently, the various possible uses and applications of display apparatuses has diversified. Furthermore, as the thickness and weight of a display apparatus are reduced, the scope of uses thereof has expanded. With the diversification of a use of a display apparatus, various methods to design the shape of a display apparatus have been researched.

The above information disclosed in this Background section is only for enhancement of understanding of the background and therefore the information discussed in this Background section does not necessarily constitute prior art.

### SUMMARY

Aspects of one or more embodiments relate to a display panel and a display apparatus including the same, and for example, to a display panel in which light transmittance in a partial area may be increased, and display apparatus including the same.

However, it is a problem that the light transmittance of a display apparatus according to the related art is not high in some areas.

One or more embodiments include a display panel in which light transmittance in some areas may be increased, and a display apparatus including the same. However, such characteristics are merely an illustration, and the scope of embodiments according to the present disclosure are not limited thereby.

Additional aspects will be set forth in part in the description which follows and, in part, will be apparent from the description, or may be learned by practice of the presented embodiments of the disclosure.

According to one or more embodiments, a display panel includes a substrate including a main display area, a component area, and a non-display area, a main pixel electrode arranged in the main display area of the substrate and including a multilayer, a main thin film transistor arranged in the main display area of the substrate and electrically connected to the main pixel electrode, an auxiliary pixel electrode arranged in the component area of the substrate and including a multilayer, an auxiliary thin film transistor arranged in the non-display area of the substrate, and an electrode connection wiring electrically connecting the auxiliary thin film transistor to the auxiliary pixel electrode and having a same structure as the auxiliary pixel.

According to some embodiments, the connection wiring may include the same material as a material forming the auxiliary pixel electrode.

According to some embodiments, the auxiliary pixel electrode may include a first lower layer, a first intermediate layer on the first lower layer, and a first upper layer on the first intermediate layer.

According to some embodiments, the thickness of the first intermediate layer of the auxiliary pixel electrode may be about 100 Å or more and about 50 Å or less.

According to some embodiments, the first upper layer and the first lower layer of the auxiliary pixel electrode may include ITO, IZO, AZO, or GZO, and the first intermediate layer of the auxiliary pixel electrode may include Ag.

According to some embodiments, the first intermediate layer of the auxiliary pixel electrode may include In of about 0.4 at % or more and about 1 at % or less.

According to some embodiments, the connection wiring may include a second lower layer, a second intermediate layer on the second lower layer, and a second upper layer on the second intermediate layer.

According to some embodiments, the thickness of the second intermediate layer of the connection wiring may be the same as the thickness of the first intermediate layer of the auxiliary pixel electrode.

According to some embodiments, the second intermediate layer of the connection wiring may include the same material as the first intermediate layer of the pixel electrode.

According to some embodiments, the second intermediate layer of the connection wiring may be integrally formed with the first intermediate layer of the pixel electrode.

According to some embodiments, each of the second lower layer and the second upper layer of the connection wiring may include the same material as the first lower layer and the first upper layer of the pixel electrode.

According to some embodiments, the second lower layer and the second upper layer of the connection wiring may be integrally formed with the first lower layer and the first upper layer of the pixel electrode, respectively.

According to some embodiments, the main pixel electrode may include a third intermediate layer and a fourth intermediate layer.

According to some embodiments, the main pixel electrode may include a third lower layer below the third intermediate layer, a fifth intermediate layer between the third intermediate layer and the fourth intermediate layer, and a third upper layer on fourth intermediate layer.

According to some embodiments, the thickness of the fourth intermediate layer of the main pixel electrode may be greater than the thickness of the third intermediate layer.

According to some embodiments, the thickness of the third intermediate layer of the main pixel electrode may be the same as the thickness of the first intermediate layer of the auxiliary pixel electrode.

According to some embodiments, the thickness of the fourth intermediate layer may be about 800 Å or more and about 1000 Å or less.

According to one or more embodiments, a display apparatus includes a display panel and an electronic element below the display panel, in which the display panel includes a substrate may include a main display area, a component area, and a non-display area, a main pixel electrode arranged in the main display area of the substrate and including a multilayer, a main thin film transistor arranged in the main display area of the substrate and electrically connected to the main pixel electrode, an auxiliary pixel electrode arranged in the component area of the substrate and including a multilayer, an auxiliary thin film transistor arranged in the non-display area of the substrate, and an electrode connection wiring electrically connecting the auxiliary thin film transistor to the auxiliary pixel electrode and having the same structure as the auxiliary pixel.

According to some embodiments, the auxiliary pixel electrode may include a first lower layer, a first intermediate layer on the first lower layer, and a first upper layer on the first intermediate layer, and the connection wiring may include a second lower layer, a second intermediate layer on the second lower layer, and a second upper layer on the second intermediate layer.

According to some embodiments, the thickness of the second intermediate layer of the connection wiring may be the same as the thickness of the first intermediate layer of the auxiliary pixel electrode, and the second intermediate layer of the connection wiring may be integrally formed with the first intermediate layer of the auxiliary pixel electrode.

### BRIEF DESCRIPTION OF THE DRAWINGS

The above and other aspects, features, and characteristics of certain embodiments of the disclosure will be more apparent from the following description taken in conjunction with the accompanying drawings, in which:

FIGS. 1A to 1C are schematic perspective views of a display apparatus according to one or more embodiments;

FIG. 2 is a schematic cross-sectional view of a portion of a display apparatus according to one or more embodiments;

FIG. 3 is a schematic plan view of a display panel included in a display apparatus according to one or more embodiments;

FIG. 4 is an equivalent circuit diagram of a pixel circuit included in the display apparatus of FIGS. 1A to 1C;

FIG. 5 is a schematic layout diagram of a partial area of a display apparatus according to one or more embodiments;

FIG. 6 is a schematic layout diagram of a partial area of a display apparatus according to one or more embodiments;

FIG. 7 is a schematic cross-sectional view of a partial area of a display apparatus according to one or more embodiments;

FIG. 8 is a schematic cross-sectional view of a region A of FIG. 7;

FIG. 9 is a schematic cross-sectional view of a partial area of a display apparatus according to one or more embodiments;

FIG. 10 is a schematic cross-sectional view of a region B of FIG. 9; and

FIGS. 11 to 14 are schematic cross-sectional views showing a method of manufacturing a main pixel electrode and an auxiliary pixel electrode, according to one or more embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, aspects of some embodiments according to the present disclosure will be described in more detail with reference to the accompanying drawings, and in the description with reference to the drawings, the same or corresponding constituents are indicated by the same reference numerals and some redundant descriptions thereof may be omitted.

In the following embodiments, it will be understood that although the terms “first,” “second,” etc. may be used herein to describe various components, these components should not be limited by these terms. These terms are only used to distinguish one component from another.

In the following embodiments, as used herein, the singular forms are intended to include the plural forms as well, unless the context clearly indicates otherwise.

In the following embodiments, it will be further understood that the terms “comprises” and/or “comprising” used herein specify the presence of stated features or components, but do not preclude the presence or addition of one or more other features or components.

In the following embodiments, it will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. For example, since sizes and thicknesses of components in the drawings are arbitrarily illustrated for convenience of explanation, the following embodiments are not limited thereto.

When certain embodiments may be implemented differently, a specific process order may be performed differently from the described order. For example, two consecutively described processes may be performed substantially at the same time or performed in an order opposite to the described order.

In the specification, the expression such as “A and/or B” may include A, B, or A and B. Furthermore, the expression such as “at least one of A and B” may include A, B, or A and B.

In the following embodiments, it will be understood that when a layer, region, or component is referred to as being “connected to” another layer, region, or component, it can be directly connected to the other layer, region, or component or indirectly connected to the other layer, region, or component via intervening layers, regions, or components. For example, in the specification, when a layer, region, or component is referred to as being electrically connected to another layer, region, or component, it can be directly electrically connected to the other layer, region, or component or indirectly electrically connected to the other layer, region, or component via intervening layers, regions, or components.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

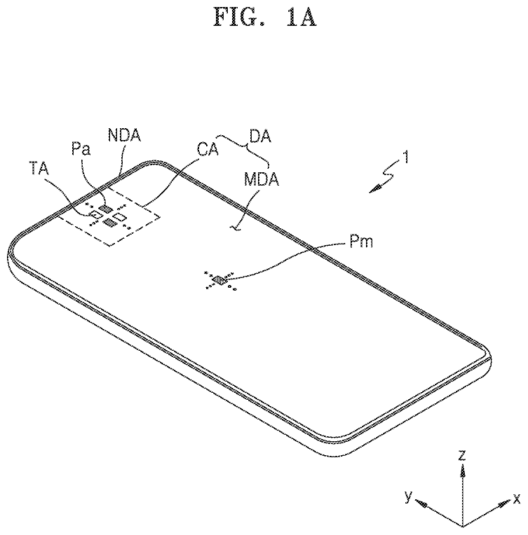

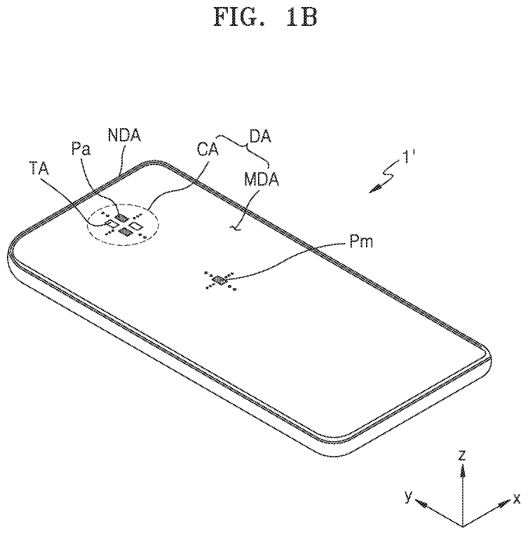

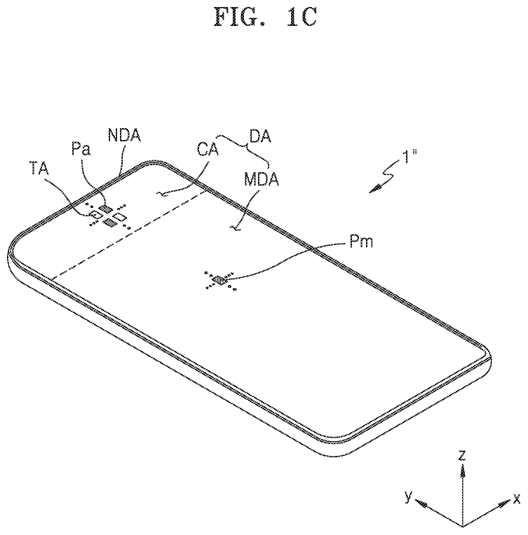

FIGS. 1A to 1C are schematic perspective views of a display apparatus 1 according to one or more embodiments.

As illustrated in FIG. 1A, the display apparatus 1 may include a display area DA and a non-display area NDA outside the display area DA. The display area DA may include a component area CA and a main display area MDA that at least partially surrounds the component area CA. As the component area CA displays an auxiliary image and the main display area MDA displays a main image, the component area CA and the main display area MDA may represent an image individually or together. The non-display area NDA may be a kind of a non-display area in which display elements are not arranged. The display area DA may be entirely surrounded by the non-display area NDA. That is, the non-display area NDA may be in a periphery of the display area DA. The display apparatus 1 including the main display area MDA, the component area CA, and the non-display area NDA may be interpreted to be a substrate of the display apparatus 1 including the main display area MDA, the component area CA, and the non-display area NDA.

FIG. 1A illustrates that the main display area MDA is positioned to surround at least part of one component area CA. In other words, one edge of the component area CA may match one edge of the main display area MDA. Alternatively, the display apparatus 1 may have two or more of the component areas CA, and the shapes and sizes of a plurality of component areas CA may different from each other. When viewed from a direction approximately perpendicular to an upper surface of the display apparatus 1 (e.g., in a plan view, or a view perpendicular or normal with respect to a display surface of the display apparatus 1), the component area CA may have various shapes, such as a circular shape, an oval shape, a polygonal shape, such as a rectangular shape and the like, a stat shape, a diamond shape, and the like.

In FIG. 1A, when viewed from the direction approximately perpendicular to the upper surface of the display apparatus 1 (e.g., in a plan view), the component area CA is positioned at the upper central portion (+y direction) of the main display area MDA having an approximately rectangular shape. However, embodiments according to the present disclosure are not limited thereto, and the component area CA may be arranged in one side of the main display area MDA that is rectangular, for example, in the upper right side or upper left side. For example, as illustrated in FIG. 1B, the component area CA that is circular may be positioned in the main display area MDA, and as illustrated in FIG. 1C, the component area CA that is of a rectangular bar type may be positioned in one side of the main display area MDA.

The display apparatus 1 may include a plurality of main sub-pixels Pm arranged in the main display area MDA and a plurality of auxiliary sub-pixels Pa arranged in the component area CA.

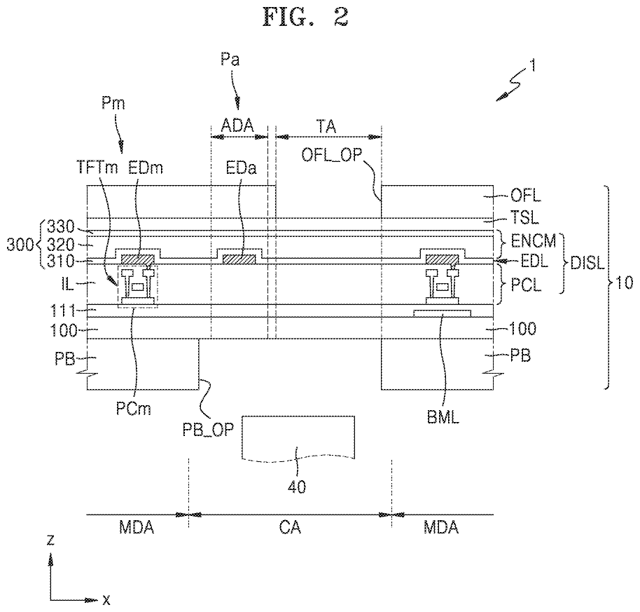

The display apparatus 1 may include a component 40 (see FIG. 2) that is an electronic element located below a display panel 10 (see FIG. 2) corresponding to the component area CA. The component 40 may be electronic elements using light or sound. For example, the electronic elements may be a sensor for measuring a distance, such as a proximity sensor, a sensor for recognizing part of the body of a user, such as a fingerprint, an iris, a face, or the like, a compact lamp for outputting light, or an image sensor for capturing an image, such as a camera.

The electronic elements using light may use light of various wavelength bands, such as visible light, infrared light, ultraviolet light, and the like. The electronic elements using sound may use ultrasound or sound of other frequency bands. According to some embodiments, the component 40 may include sub-components, such as a light-emitting unit and a light-receiving unit. The light-emitting unit and the light-receiving unit may have an integrated structure or a physically separated structure so that a pair of a light-emitting unit and a light-receiving unit may form one component 40. To reduce a limitation of the function of the component 40, the component area CA may include a transmissive area TA through which light or/and sound and the like output from the component 40 to the outside or traveling toward the component 40 from the outside may transmit.

For a display apparatus according to one or more embodiments, when light is transmitted through the component area CA, a light transmittance may be about 10% or more, about 40% or more, about 50% or more, about 85% or more, or about 90% or more.

The auxiliary sub-pixels Pa may be arranged in the component area CA. The auxiliary sub-pixels Pa may provide a certain image by emitting light. The image displayed in the component area CA is an auxiliary image, and may have a resolution lower than the image display in the main display area MDA. In other words, the component area CA may include the transmissive area TA through which light and sound is transmitted, and when sub-pixels are not arranged in the transmissive area TA, the number of the auxiliary sub-pixels Pa to be arranged per unit area may be less than the number of the main sub-pixels Pm to be arranged in the main display area MDA per unit area.

In the following description, for example, an organic light-emitting display apparatus is described as the display apparatus 1 according to one or more embodiments. However, the display apparatus is not limited thereto. In other words, the display apparatus 1 may include an inorganic light-emitting display apparatus (or an inorganic electroluminescent (EL) display apparatus) or a quantum-dot light-emitting display apparatus. For example, an emission layer of a display element in the display apparatus 1 may include an organic material or an inorganic material. The display apparatus 1 may include quantum dots, an organic material and quantum dots, or an inorganic material and quantum dots.

FIG. 2 is a schematic cross-sectional view of a portion of the display apparatus 1, according to one or more embodiments. As illustrated in FIG. 2, the display apparatus 1 may include a display panel 10 and the component 40 arranged to overlap the display panel 10. According to some embodiments, the display apparatus 1 may further include cover window that is arranged above the display panel 10 to protect the display panel 10.

The display panel 10 may include the component area CA that is an area overlapping the component 40 and the main display area MDA in which a main image is displayed. The display panel 10 may include a substrate 100, a display layer DISL on the substrate 100, a touchscreen layer TSL, an optical functional layer OFL, and a panel protective member PB below the substrate 100. A buffer layer 111 may be provided between the substrate 100 and the display layer DISL.

The display layer DISL may include a circuit layer PCL, a display element layer EDL, and an encapsulation member ENCM. The circuit layer PCL may include thin film transistors TFTm and TFTa. The display element layer EDL may include light-emitting elements EDm and EDa that are display elements. The encapsulation member ENCM may include a thin film encapsulation layer 300 or a sealing substrate. An insulating layer IL may be arranged in the display layer DISL and the like.

The substrate 100 may include an insulating material, such as glass, quartz, polymer resin, and the like. The substrate 100 may be a rigid substrate or a flexible substrate that is bendable, foldable, rollable, or the like.

A main light-emitting element EDm and a main pixel circuit PCm connected thereto may be arranged in the main display area MDA of the display panel 10. The main pixel circuit PCm may include at least one main thin film transistor TFTm, and may control the operation of the main light-emitting element EDm. A main sub-pixel Pm may include the main light-emitting element EDm described above.

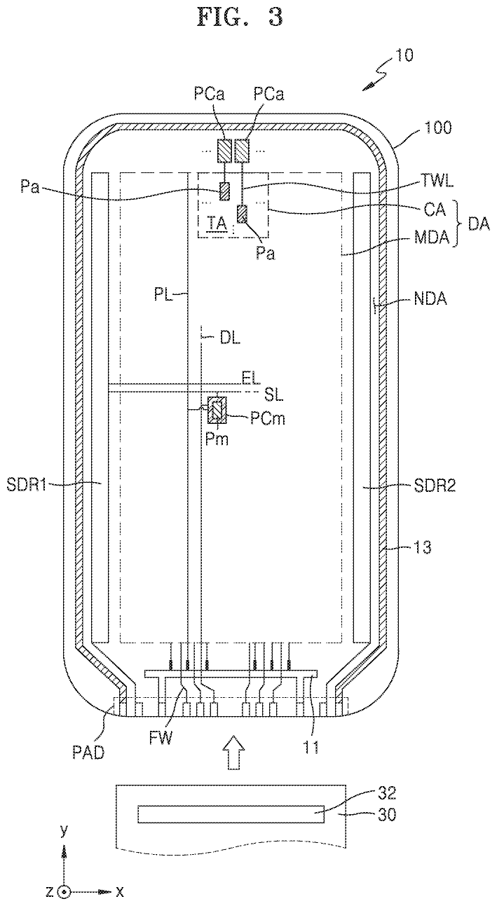

An auxiliary light-emitting element EDa may be arranged in the component area CA of the display panel 10. The auxiliary light-emitting element EDa may also be connected to an auxiliary pixel circuit PCa (see FIG. 3), and the auxiliary pixel circuit PCa may be positioned in the non-display area NDA, not in the component area CA. The auxiliary pixel circuit PCa may include at least one thin film transistor, and may control the operation of the auxiliary light-emitting element EDa. Each of the auxiliary sub-pixels Pa may include the auxiliary light-emitting element EDa.

An area of the component area CA, in which the auxiliary light-emitting element EDa is arranged, may be defined as an auxiliary display area ADA, and an area of the component area CA, in which the auxiliary light-emitting element EDa is not arranged, may be defined as the transmissive area TA.

The transmissive area TA may be an area through which light/signal emitted from the component arranged corresponding to the component area CA or light/signal incident on the component 40 is transmitted. The auxiliary display area ADA and the transmissive area TA may be alternately arranged in the component area CA.

The display element layer EDL may be covered by the thin film encapsulation layer 300, as illustrated in FIG. 2. For example, the thin film encapsulation layer 300 may include, as illustrated in FIG. 2, at least one inorganic encapsulation layer and at least one organic encapsulation layer. In FIG. 2, the thin film encapsulation layer 300 is illustrated as including a first inorganic encapsulation layer 310, a second inorganic encapsulation layer 330, and an organic encapsulation layer 320 provided therebetween.

The first inorganic encapsulation layer 310 and the second inorganic encapsulation layer 330 may each include one or more inorganic insulating materials, such as a silicon oxide SiO₂, a silicon nitride SiNx, a silicon oxynitride SiOxNy, an aluminum oxide Al₂O₃, a titanium oxide TiO₂, a tantalum oxide Ta₂O₅, a hafnium oxide HfO₂, or a zinc oxide ZnO₂, and may be formed by a chemical vapor deposition (CVD) method and the like. The organic encapsulation layer 320 may include a polymer-based material. The polymer-based material may include silicon-based resin, acrylic resin, for example, polymethylmethacrylate, polyacrylic acid, and the like, epoxy-based resin, polyimide, polyethylene, and the like. Each of the first inorganic encapsulation layer 310, the organic encapsulation layer 320, and the second inorganic encapsulation layer 330 may be integrally formed to cover the main display area MDA and the component area CA.

Embodiments according to the present disclosure are not limited thereto, and the display panel 10 may include a sealing substrate on the display element layer EDL. In this case, the sealing substrate may be arranged to face the substrate 100 with the display element layer EDL therebetween. A gap may exist between the sealing substrate and the display element layer EDL. The sealing substrate may include glass. A sealant made of frit is arranged between the substrate 100 and the sealing substrate, and the sealant may be arranged in the non-display area NDA described above. The sealant arranged in the non-display area NDA and surrounding the display area DA may prevent or reduce infiltration of moisture through a side surface.

The touchscreen layer TSL may obtain an external input, for example, coordinates information according to a touch event. The touchscreen layer TSL may include a touch electrode and touch wirings connected to the touch electrode. The touchscreen layer TSL may sense an external input by a self-capacitance method or a mutual capacitance method.

The touchscreen layer TSL may be located on the thin film encapsulation layer 300. Alternatively, the touchscreen layer TSL may be separately formed on a touch substrate and then bonded to the thin film encapsulation layer 300 via an adhesive layer, such as an optically clear adhesive OCA. According to some embodiments, the touchscreen layer TSL may be formed directly on the thin film encapsulation layer 300, and in this case, the adhesive layer may not be provided between the touchscreen layer TSL and the thin film encapsulation layer 300.

The optical functional layer OFL may include an antireflective layer. The antireflective layer may reduce the reflectivity of light (external light) incident on the display apparatus 1 from the outside. For example, the optical functional layer OFL may be a polarization film. The optical functional layer OFL may have an opening OFL_OP corresponding to the transmissive area TA. Accordingly, the light transmittance of the transmissive area TA may be remarkably improved. The opening OFL OP may be filled with a transparent material, such as optically clear resin (OCR). Alternatively, the optical functional layer OFL may be implemented in a filter plate including a black matrix and color filters.

The panel protective member PB is attached to a lower portion of the substrate 100, and may support and protect the substrate 100. The panel protective member PB may have an opening PB_OP corresponding to the component area CA. As the panel protective member PB has the opening PB_OP, light transmittance in the component area CA may be improved. The panel protective member PB may include polyethylene terephthalate or polyimide.

The area of the component area CA may be greater than the area in which the component 40 is arranged. Accordingly, the area of the opening PB_OP of the panel protective member PB may not match the area of the component area CA. Although FIG. 2 illustrates that the component 40 is spaced apart from the display panel 10 in one side of the display panel 10 (−z direction), at least a part of the component 40 may be inserted into the opening PB_OP in the panel protective member PB.

Furthermore, a plurality of components 40 may be arranged in the component area CA. In this case, the components 40 may have different functions. For example, the components 40 may include at least two of a camera (photographing element), a solar cell, a flash, a proximity sensor, an illuminance sensor, and an iris sensor.

FIG. 3 is a schematic plan view of a display panel included in a display apparatus according to one or more embodiments. In detail, FIG. 3 may be understood as a plan view that schematically shows a display panel that the display apparatus 1 of FIG. 1A may include. Referring to FIG. 3, various constituent elements forming the display panel 10 may be arranged on the substrate 100.

The main sub-pixels Pm may be arranged in the main display area MDA. The main sub-pixels Pm may each be implemented by a display element, such as an organic light-emitting diode OLED. The main pixel circuit PCm that drives the main sub-pixel Pm is arranged in the main display area MDA, and the main pixel circuit PCm may be arranged to overlap the main sub-pixel Pm. Each main sub-pixel Pm may emit, for example, red, green, blue, or white light. The main display area MDA may be covered by an encapsulation member and protected from external air, moisture, or the like.

The component area CA may be positioned in one side of the main display area MDA, as described above, or arranged inside the display area DA to be surrounded by the main display area MDA. The auxiliary sub-pixels Pa may be arranged in the component area CA. The auxiliary sub-pixels Pa may each be implemented by a display element, such as the organic light-emitting diode OLED. The auxiliary pixel circuit PCa electrically connected to an auxiliary sub-pixel Pa positioned in the component area CA may be arranged in the non-display area NDA. Each auxiliary sub-pixel Pa may emit, for example, red, green, blue, or white light. The component area CA is covered with the main display area MDA together by an encapsulation member, to be protected from external air, moisture, or the like.

As such, the auxiliary pixel circuit PCa that drives the auxiliary sub-pixels Pa of the component area CA may be arranged in the non-display area NDA adjacent to the component area CA. As illustrated in FIG. 3, when the component area CA is arranged in the upper side of the display area DA (+y direction), the auxiliary pixel circuit PCa may be arranged in the non-display area NDA in the upper side. The display element that implements the auxiliary pixel circuit PCa and the auxiliary sub-pixel Pa may be connected by a connection wiring TWL extending in one direction (for example, y direction). Although FIG. 3 illustrates that the auxiliary pixel circuit PCa is positioned directly above the component area CA, embodiments according to the present disclosure are not limited thereto. For example, the auxiliary pixel circuit PCa may be variously modified, for example, to be positioned in the left side (−x direction) or right side (+x direction) of the main display area MDA.

As described above, the component area CA may have the transmissive area TA. The transmissive area TA may be arranged to surround the auxiliary sub-pixels Pa. Alternatively, the transmissive area TA may be arranged in a grid shape with the auxiliary sub-pixels Pa. As the component area CA has the transmissive area TA, the resolution of the component area CA may be less than the resolution of the main display area MDA. For example, the resolution of the component area CA may be about ½, ⅜, ⅓, ¼, 2/9, ⅛, 1/9, 1/16, or the like of the resolution of the main display area MDA. For example, the resolution of the main display area MDA may be about 400 ppi or more, and the resolution of the component area CA may be about 200 ppi or about 100 ppi.

Each of the pixel circuits PCm and PCa that drive the sub-pixels Pm and Pa, respectively, may be electrically connected to outer circuits arranged in the non-display area NDA. A first scan drive circuit SDR1, a second scan drive circuit SDR2, a terminal portion PAD, a drive voltage supply line 11, and a common voltage supply line 13 may be arranged in the non-display area NDA.

The first scan drive circuit SDR1 and the second scan drive circuit SDR2 may be arranged symmetrically with respect to the main display area MDA. The first scan drive circuit SDR1 and the second scan drive circuit SDR2 may apply, via a scan line SL, scan signals to the main pixel circuit PCm that drives the main sub-pixel Pm. Furthermore, the first scan drive circuit SDR1 and the second scan drive circuit SDR2 may apply emission control signals to each pixel circuit via an emission control line EL. Some of the main pixel circuit PCm of the main sub-pixel Pm of the main display area MDA may be electrically connected to the first scan drive circuit SDR1, and the other may be electrically connected to the second scan drive circuit SDR2.

The terminal portion PAD may be arranged in one side of the substrate 100. The terminal portion PAD may be electrically connected to a display circuit board 30 and exposed without being covered by an insulating layer. A display driving portion 32 may be arranged in the display circuit board 30.

The display driving portion 32 may generate control signals that are transmitted to the first scan drive circuit SDR1 and the second scan drive circuit SDR2. The display driving portion 32 may generate data signals, and the generated data signals may be transmitted to the main pixel circuit PCm via a fan-out wiring FW and a data line DL connected to the fan-out wiring FW.

The display driving portion 32 may supply a driving voltage ELVDD to the drive voltage supply line 11, and a common voltage ELVSS to the common voltage supply line 13. The driving voltage ELVDD may be applied to the pixel circuits of the sub-pixels Pm and Pa via a driving voltage line PL connected to the drive voltage supply line 11, and the common voltage ELVSS, which is connected to the common voltage supply line 13, may be applied to a counter electrode of the display element.

The drive voltage supply line 11 may extend from a lower side of the main display area MDA in the x direction. The common voltage supply line 13 has a loop shape with one open side, and may partially surround the main display area MDA.

Although FIG. 3 illustrates a case in which the component area CA is one, the display panel 10 may include a plurality of component areas CA. In this case, the component areas CA are spaced apart from each other, and a first camera may be arranged corresponding to one component area CA and a second camera may be arranged corresponding to another component area CA. Alternatively, a camera may be arranged corresponding to one component area CA, and an infrared sensor may be arranged corresponding to another component area CA. The shapes and sizes of the component areas CA may be different from each other.

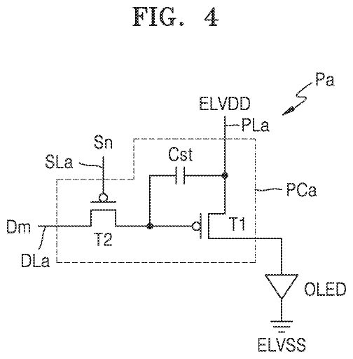

FIG. 4 is an equivalent circuit diagram of a pixel circuit included in the display apparatus 1 of FIGS. 1A to 1C. As illustrated in FIG. 4, the auxiliary sub-pixel Pa may include the auxiliary pixel circuit PCa and the organic light-emitting diode OLED as a display element connected to the auxiliary pixel circuit PCa. The main sub-pixel Pm may also include the main pixel circuit PCm that is the same as or similar to the auxiliary pixel circuit PCa, as illustrated in FIG. 4, and the organic light-emitting diode OLED as a display element connected to the main pixel circuit PCm.

As illustrated in FIG. 4, the auxiliary pixel circuit PCa may include a drive thin film transistor T1, a switching thin film transistor T2, and a storage capacitor Cst. The switching thin film transistor T2 is connected to an auxiliary scan line SLa and an auxiliary data line DLa, and may transmit a data signal Dm input through the auxiliary data line DLa to the drive thin film transistor T1, in response to a scan signal Sn input through the auxiliary scan line SLa. The storage capacitor Cst is connected to the switching thin film transistor T2 and an auxiliary driving voltage line PLa, and may store a voltage corresponding to a difference between the voltage received from the switching thin film transistor T2 and the driving voltage ELVDD supplied through the auxiliary driving voltage line PLa.

The drive thin film transistor T1 is connected to the auxiliary driving voltage line PLa and the storage capacitor Cst, and may control a drive current from the auxiliary driving voltage line PLa and flowing in the organic light-emitting diode OLED, in response to a voltage value stored in the storage capacitor Cst. The organic light-emitting diode OLED may emit light having a certain luminance by the drive current.

Although FIG. 4 illustrates that the auxiliary pixel circuit PCa includes two thin film transistors and one storage capacitor, embodiments according to the present disclosure are not limited thereto. For example, the auxiliary pixel circuit PCa may seven thin film transistors and one storage capacitor. Alternatively, the auxiliary pixel circuit PCa may include two or more storage capacitors.

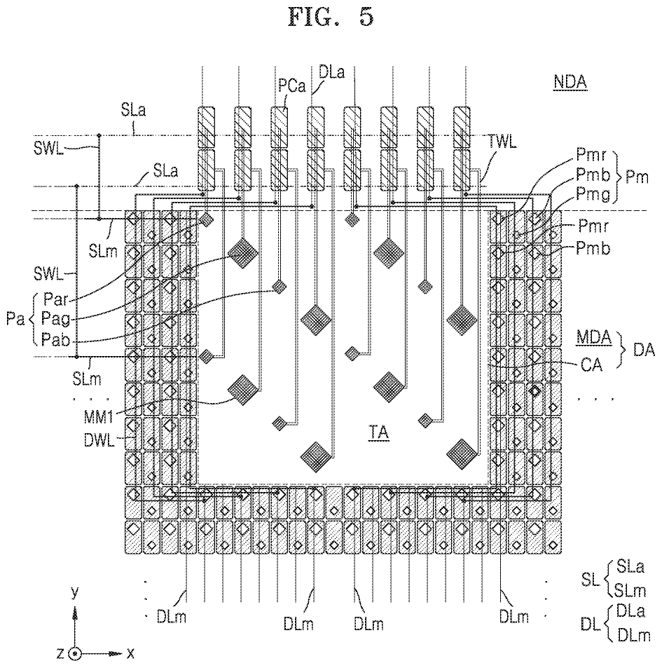

FIG. 5 is a schematic layout diagram of a partial area of a display apparatus according to one or more embodiments. In detail, FIG. 5 illustrates the component area CA, and parts of the main display area MDA and the non-display area NDA adjacent thereto.

Referring to FIG. 5, the main sub-pixels Pm may be arranged in the main display area MDA. A sub-pixel, as a minimum unit for realizing an image, may mean a light-emitting area in which light is emitted by a display element. When the organic light-emitting diode OLED is employed as a display element, the light-emitting area may be defined by an opening of a pixel defining layer, which is as described above. Each of the main sub-pixels Pm may emit any one of red, green, blue, and white light.

The main sub-pixel Pm arranged in the main display area MDA may include a first sub-pixel Pmr, a second sub-pixel Pmg, and a third sub-pixel Pmb. The first sub-pixel Pmr, the second sub-pixel Pmg, and the third sub-pixel Pmb may implement red, green, and blue colors, respectively. The main sub-pixels Pm may be arranged in a Pentile structure.

For example, the first sub-pixels Pmr are arranged at a first vertex and a third vertex facing each other among the vertexes of a virtual rectangle having a center point of the second sub-pixel Pmg as a center point of the rectangle, and the third sub-pixels Pmb may be arranged at the other vertexes that are a second vertex and a fourth vertex. According to some embodiments, the size, that is, the light-emitting area, of the second sub-pixel Pmg may be less than the size, that is, the light-emitting area, of the first sub-pixel Pmr, and the size, that is, the light-emitting area, of the third sub-pixel Pmb.

The above pixel arrangement structure is referred to as a Pentile matrix structure or Pentile structure, and a high resolution may be implemented with a small number of pixels by employing rendering driving that represents a color by sharing adjacent pixels.

Although FIG. 5 illustrates that the main sub-pixels Pm are arranged in a Pentile matrix structure, embodiments according to the present disclosure are not limited thereto. For example, the main sub-pixels Pm may be arranged in various shapes, such as a stripe structure, a mosaic arrangement structure, a delta arrangement structure, and the like.

In the main display area MDA, the main pixel circuit PCms may be arranged to overlap the main sub-pixels Pm, and the main pixel circuit PCms may be arranged in a matrix shape in the x direction and the y direction. In the specification, the main pixel circuit PCm may mean a unit of a pixel circuit that implements one main sub-pixel Pm.

The auxiliary sub-pixels Pa may be arranged in the component area CA. Each of the main sub-pixels Pm may emit any one of red, green, blue, and white light. The auxiliary sub-pixels Pa may include a first sub-pixel Par, a second sub-pixel Pag, and a third sub-pixel Pab, which emit light of different colors. The first sub-pixel Par, the second sub-pixel Pag, and the third sub-pixel Pab may implement red, green, and blue colors, respectively.

The number per unit area of the auxiliary sub-pixels Pa arranged in the component area CA may be less than the number per unit area of the main sub-pixels Pm arranged in the main display area MDA. For example, a ratio of the number of the auxiliary sub-pixels Pa and the number of the main sub-pixels Pm, which are arranged in the same area, may be 1:2, 1:4, 1:8, or 1:9. In other words, the resolution of the component area CA may be ½, ¼, ⅛, or 1/9 of the resolution of the main display area MDA. FIG. 5 illustrates a case in which the resolution of the component area CA is ⅛.

The auxiliary sub-pixels Pa arranged in the component area CA may be arranged in various shapes. Some of the auxiliary sub-pixels Pa may gather to form a pixel group, and may be arranged in the pixel group in various shapes, such as a Pentile structure, a stripe structure, a mosaic arrangement structure, a delta arrangement structure, and the like. In this state, a distance between the auxiliary sub-pixels Pa arranged in a pixel group may be the same as a distance between the main sub-pixels Pm.

Alternatively, as illustrated in FIG. 5, the auxiliary sub-pixels Pa may be arranged and distributed in the component area CA. In other words, the distance between the auxiliary sub-pixels Pa may be greater than the distance between the main sub-pixels Pm. An area in the component area CA, in which the auxiliary sub-pixels Pa are not arranged, may be referred to as the transmissive area TA having high light transmittance, as described above.

The auxiliary pixel circuits PCa that implement the light-emitting of the auxiliary sub-pixels Pa may be arranged in the non-display area NDA. As the auxiliary pixel circuits PCa are not arranged in the component area CA, the component area CA may secure a large area for the transmissive area TA.

The auxiliary pixel circuits PCa may be connected to the auxiliary sub-pixels Pa by the connection wirings TWL. Accordingly, when the length of the connection wiring TWL increases, a resistance-capacitance (RC) delay phenomenon may occur, and thus, the auxiliary pixel circuits PCa may be arranged considering the length of the connection wirings TWL.

According to some embodiments, the auxiliary pixel circuits PCa may be arranged on an extended line that connects the auxiliary sub-pixels Pa arranged in the y direction. Furthermore, the auxiliary pixel circuits PCa may be arranged in the y direction as many as the number of the auxiliary sub-pixels Pa arranged in the y direction. For example, as illustrated in FIG. 5, when two auxiliary sub-pixels Pa are arranged in the component area CA in the y direction, two auxiliary pixel circuits PCa may be arranged in the non-display area NDA in the y direction.

The connection wirings TWL may extend in they direction, and the auxiliary sub-pixels Pa and the auxiliary pixel circuits PCa may be connected to each other. The connection wiring TWL being connected to the auxiliary sub-pixel Pa may mean that the connection wiring TWL is electrically connected to a pixel electrode of a display element that implements the auxiliary sub-pixel Pa.

The scan line SL may include a main scan line SLm connected to the main pixel circuit PCms and the auxiliary scan line SLa connected to the auxiliary pixel circuits PCa. The main scan line SLm extending in the x direction may be connected to the main pixel circuit PCms arranged in the same row. The main scan line SLm may not be arranged in the component area CA. In other words, the main scan line SLm may be disconnected in the component area CA between the left side of the component area CA and the right side of the component area CA. In this case, the main scan line SLm arranged in the left side of the component area CA may receive signals from the first scan drive circuit SDR1 of FIG. 3, and the main scan line SLm arranged in the right side of the component area CA may receive signals from the second scan driving circuit SDR2 of FIG. 3.

The auxiliary scan line SLa extending in the x direction may be connected to the auxiliary pixel circuits PCa arranged in the same row. The auxiliary scan line Sla may be arranged in the non-display area NDA.

The main scan line SLm and the auxiliary scan line SLa may be connected by a scan connection line SWL, and thus, the same signal may be applied to pixel circuits that drive the main sub-pixel Pm and the auxiliary sub-pixel Pa arranged in the same row. The scan connection line SWL may be arranged on a different layer from the main scan line SLm and the auxiliary scan line SLa, and thus, the scan connection line SWL may be connected to each of the main scan line SLm and the auxiliary scan line SLa through contact holes. The scan connection line SWL may be arranged in the non-display area NDA.

The data line DL may include a main data line DLm connected to the main pixel circuit PCms and the auxiliary data line DLa connected to the auxiliary pixel circuits PCa. The main data line DLm extending in the y direction may be connected to the main pixel circuit PCms arranged in the same column. The auxiliary data line DLa extending in the y direction may be connected to the auxiliary pixel circuits PCa arranged in the same column.

The main data line DLm and the auxiliary data line DLa may be arranged spaced apart from each other with the component area CA therebetween. The main data line DLm and the auxiliary data line DLa are connected via a data connection line DWL, and thus, the same signal may be applied to the pixel circuits for driving the main sub-pixel Pm and the auxiliary sub-pixel Pa arranged in the same column.

The data connection line DWL may be arranged to bypass the component area CA. According to some embodiments, the data connection line DWL may be arranged to overlap the main pixel circuit PCms arranged in the main display area MDA. As the data connection line DWL is arranged in the main display area MDA, there is no need to secure a separate space in which the data connection line DWL is arranged, and thus, a dead space area may be reduced.

According to some embodiments, the data connection line DWL may be arranged in a middle area between the main display area MDA and the component area CA.

The data connection line DWL is arranged on a layer different from the main data line DLm and the auxiliary data line DLa, and may be connected to each of the main data line DLm and the auxiliary data line DLa via contact holes.

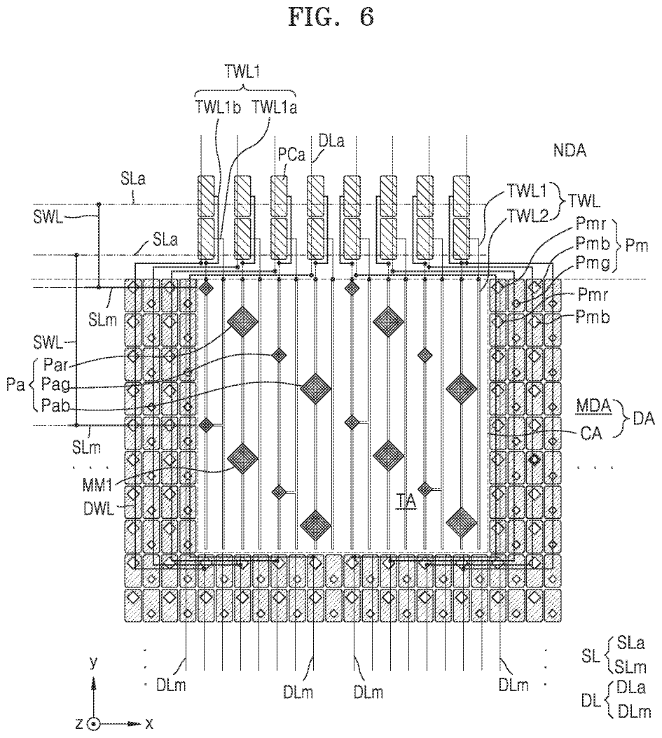

FIG. 6 is a schematic layout diagram of a partial area of a display apparatus according to one or more embodiments.

Although FIG. 5 illustrates that the connection wiring TWL is integrally formed from the non-display area NDA to the auxiliary sub-pixels Pa of the component area CA, embodiments according to the present disclosure are not limited thereto. For example, the connection wiring TWL may include, as illustrated in FIG. 6, a first connection wiring TWL1 and a second connection wiring TWL2, which are made of different materials.

The first connection wiring TWL1 may be arranged in the non-display area NDA and connected to the auxiliary pixel circuit PCa. The first connection wiring TWL1 may include a conductive material including molybdenum (Mo), aluminum (Al), copper (Cu), titanium (Ti), and the like, and may have a multilayer or single layer structure including the materials.

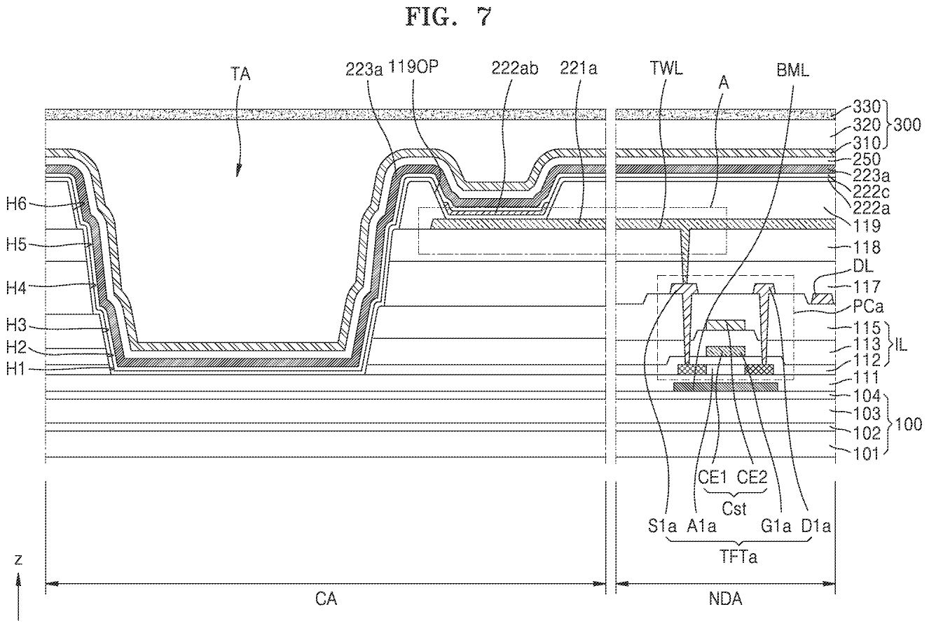

The first connection wiring TWL1 may include a plurality of first connection wirings between the auxiliary pixel circuits PCa. For example, the first connection wiring TWL1 may include a first-1 connection wiring TWL1a and a first-2 connection wiring TWL1b, which are arranged in different layers. The first-1 connection wiring TWL1a is arranged in the same layer as the data line DL (see FIG. 7) and may include the same material as the data line DL. The first-2 connection wiring TWL1b and the first-1 connection wiring TWL1a may be arranged with an insulating layer therebetween. The first-1 connection wiring TWL1a and the first-2 connection wiring TWL1b may be arranged between the auxiliary pixel circuit PCa, and may have a shape of at least a part thereof is bent when viewed from a direction perpendicular to the substrate 100. The first-1 connection wiring TWL1a and the first-2 connection wiring TWL1b arranged in different layers may each include a plurality of connection wirings, and the first-1 connection wiring TWL1a and the first-2 connection wiring TWL1b may be alternately arranged in an area between the auxiliary pixel circuits PCa.

The second connection wiring TWL2 may be arranged in the component area CA and connected to the first connection wiring TWL1 at the edge of the component area CA. The second connection wiring TWL2 may include a transparent conductive material. In other words, the second connection wiring TWL2 may be formed of the same material as that of the connection wiring TWL and in the same structure, as in the embodiments described above.

The first connection wiring TWL1 and the second connection wiring TWL2 may be arranged in the same layer, or in different layers. When the first connection wiring TWL1 and the second connection wiring TWL2 are arranged in different layers, they may be connected to each other via a contact hole.

The conductivity of the first connection wiring TWL1 may be greater than the conductivity of the second connection wiring TWL2. As the first connection wiring TWL1 is arranged in the non-display area NDA, there is no need to secure a light transmittance, and thus, the first connection wiring TWL1 may include a material having a lower light transmittance, but a higher conductivity, than that of the second connection wiring TWL2. Accordingly, the resistance value of the connection wiring TWL may be reduced.

As illustrated in FIG. 6, the lengths of the second connection wirings TWL2 may be the same. For example, ends of the second connection wirings TWL2 may extend to the boundary of the component area CA at the opposite side where the auxiliary pixel circuits PCa are arranged. This is to match an electrical load by the second connection wiring TWL2. Accordingly, luminance deviation may be reduced in the component area CA. The number of the second connection wiring TWL2 in the component area CA may be the same as the number of the auxiliary pixel circuits PCa.

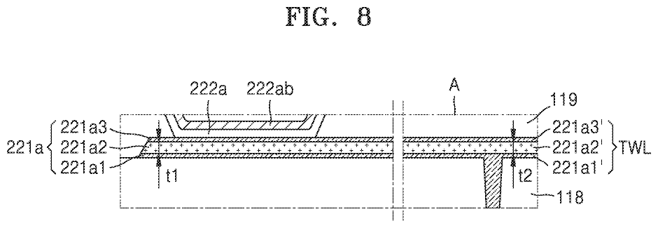

FIG. 7 is a schematic cross-sectional view of a partial area of a display apparatus according to one or more embodiments. In FIG. 7, a part of the component area CA and a part of the non-display area NDA are illustrated. FIG. 8 is a schematic cross-sectional view of a region A of FIG. 7.

The substrate 100 may include various materials and may have a multilayer structure, as illustrated in FIG. 7. In detail, the substrate 100 may include a first base layer 101, a first inorganic layer 102, a second base layer 103, and a second inorganic layer 104, which are sequentially stacked.

The first base layer 101 and the second base layer 103 may each include polymer resin. The polymer resin may include polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. The polymer resin may be transparent.

The first inorganic layer 102 and the second inorganic layer 104 may be barrier layers that prevents or reduces infiltration of an external foreign material. The first inorganic layer 102 and the second inorganic layer 104 may each be a single layer or multilayer including an inorganic material, such as a silicon nitride, a silicon oxynitride, and/or a silicon oxide.

The buffer layer 111 may reduce or prevent infiltration of foreign materials, moisture, or external air from under the substrate 100, and may serve to planarize an upper surface of the substrate 100. The buffer layer 111 may include an inorganic insulating material, such as a silicon oxide, a silicon oxynitride, or a silicon nitride, and may have a single layer or multilayer structure including the material described above.

The auxiliary pixel circuit PCa including an auxiliary thin film transistor TFTa and the storage capacitor Cst arranged in non-display area NDA may be arranged on the buffer layer 111. The main pixel circuit PCm that is not illustrated in FIG. 6 may be arranged in the main display area MDA. The main pixel circuit PCm of the main display area MDA and the auxiliary pixel circuit PCa of the component area CA may have the same structure. However, embodiments according to the present disclosure are not limited thereto. The main pixel circuit PCm of the main display area MDA and the auxiliary pixel circuit PCa of the component area CA may have different structures.

A backside metal layer BML may be arranged between the auxiliary pixel circuit PCa and the substrate 100 arranged in the non-display area NDA. The backside metal layer BML may prevent or reduce diffraction of light emitted from the component or traveling toward the component 40 through a narrow gap between the wirings in the component area CA. The backside metal layer BML does not exist in the transmissive area TA. For example, the backside metal layer BML may have opening portions BMLA corresponding to the transmissive area TA. In other words, the opening portions BMLA of the backside metal layer BML may define the transmissive area TA of the component area CA.

As necessary, the backside metal layer BML may be positioned in the main display area MDA, and may improve the performance of the main thin film transistor TFTm of the main pixel circuit PCm. In this case, the backside metal layer BML may be positioned in a main semiconductor layer A1m below the main thin film transistor TFTm.

The auxiliary thin film transistor TFTa of the auxiliary pixel circuit PCa positioned in the non-display area NDA may include an auxiliary semiconductor layer A1a, an auxiliary gate electrode G1a overlapping a channel region of the auxiliary semiconductor layer A1a, and a source electrode S1a and a drain electrode D1a respectively connected to a source region and a drain region of the auxiliary semiconductor layer A1a. A gate insulating layer 112 may be arranged between the auxiliary semiconductor layer A1a and the auxiliary gate electrode G1a, and a first interlayer insulating layer 113 and a second interlayer insulating layer 115 may be arranged between the auxiliary gate electrode G1a and the source electrode S1a or between the auxiliary gate electrode G1a and the drain electrode D1a.

The storage capacitor Cst may be arranged to overlap a thin film transistor TFT. The storage capacitor Cst may include a first capacitor plate CE1 and a second capacitor plate CE2 overlapping each other. According to some embodiments, the auxiliary gate electrode G1a of the auxiliary thin film transistor TFTa and the first capacitor plate CE1 of the storage capacitor Cst may form one body. The first interlayer insulating layer 113 may be arranged between the first capacitor plate CE1 and the second capacitor plate CE2.

The auxiliary semiconductor layer A1a may include polysilicon. Alternatively, the auxiliary semiconductor layer A1a may include amorphous silicon. Alternatively, the auxiliary semiconductor layer A1a may include an oxide of at least one material selected from indium (In), gallium (Ga), tin (Sn), zirconium (Zr), vanadium (V), hafnium (Hf), cadmium (Cd), germanium (Ge), chromium (Cr), Ti, and zinc (Zn). The auxiliary semiconductor layer A1a may include the channel region, and the source region and the drain region, which are doped with impurities.

The gate insulating layer 112 may include an inorganic insulating material, such as a silicon oxide, a silicon oxynitride, or a silicon nitride, and may have a single layer or multilayer structure including the material.

The auxiliary gate electrode G1a or the first capacitor plate CE1 may include a low-resistance conductive material, such as Mo, Al, Cu, and/or Ti, and may have a single layer or multilayer structure including the material described above. For example, the auxiliary gate electrode G1a may have a three-layer structure of a molybdenum layer/an aluminum layer/a molybdenum layer.

The first interlayer insulating layer 113 may include an inorganic insulating material, such as a silicon oxide, a silicon oxynitride, and a silicon nitride, and may have a single layer or multilayer structure including the material.

The second capacitor plate CE2 may include Al, platinum (Pt), palladium (Pd), silver (Ag), magnesium (Mg), gold (Au), nickel (Ni), neodymium (Nd), iridium (Ir), chromium (Cr), Ni, calcium (Ca), Mo, Ti, tungsten (W), and/or Cu, and may have a single layer or multilayer structure including the material.

The second interlayer insulating layer 115 may include an inorganic insulating material, such as a silicon oxide, a silicon oxynitride, or a silicon nitride, and may have a single layer or multilayer structure including the material.

The source electrode S1a or the drain electrode D1a may include Al, Pt, Pd, Ag, Mg, Au, Ni, Nd, Ir, Cr, Ni, Ca, Mo, Ti, W, and/or Cu, and may have a single layer or multilayer structure including the material. For example, the source electrode S1a or the drain electrode D1a may have a three-layer structure of a titanium layer/an aluminum layer/a titanium layer.

The auxiliary pixel circuit PCa including the auxiliary thin film transistor TFTa and the storage capacitor Cst may be electrically connected to an auxiliary pixel electrode 221a positioned in the component area CA. For example, as illustrated in FIG. 7, the auxiliary pixel circuit PCa and the auxiliary pixel electrode 221a may be electrically connected to each other by the connection wiring TWL. Although FIG. 7 illustrates that the connection wiring TWL electrically connects the source electrode S1a of the auxiliary pixel circuit PCa to the auxiliary pixel electrode 221a, embodiments according to the present disclosure are not limited thereto. Various modifications, for example, the connection wiring TWL electrically connects the drain electrode D1a of the auxiliary pixel circuit PCa to the auxiliary pixel electrode 221a, are possible.

A first planarization layer 117 covering the auxiliary thin film transistor TFTa may include an organic insulating material. The first planarization layer 117 may include an organic insulating material, such as acryl, benzocyclobutene (BCB), polyimide, hexamethyldisiloxane (HMDSO), or the like. The organic insulating material of the first planarization layer 117 may be a photosensitive organic insulating material.

A second planarization layer 118 on the first planarization layer 117 may include an organic insulating material. The second planarization layer 118 may include an organic insulating material, such as acryl, BCB, polyimide, HMDSO, or the like. The organic insulating material of the second planarization layer 118 may be a photosensitive organic insulating material. A wiring may be arranged between the first planarization layer 117 and the second planarization layer 118, as necessary.

The auxiliary pixel electrode 221a may be arranged on the second planarization layer 118. The auxiliary pixel electrode 221a may be electrically connected to the auxiliary thin film transistor TFTa via the connection wiring TWL.

The auxiliary pixel electrode 221a may include a reflective film including Ag, Mg, Al, Pt, Pd, Au, Ni, Nd, Ir, Cr, or a compound thereof. The auxiliary pixel electrode 221a may include a reflective film including the above material, and a transparent conductive film arranged above or/and below the reflective film. The transparent conductive film may include an indium tin oxide (ITO), an indium zinc oxide (IZO), a zinc oxide (ZnO), an indium oxide (In₂O₃), an indium gallium oxide (IGO), an aluminum zinc oxide (AZO), and the like.

According to some embodiments, the auxiliary pixel electrode 221a may include a multilayer. The auxiliary pixel electrode 221a may have a three-layer structure. The auxiliary pixel electrode 221a may include a first lower layer 221a1, a first intermediate layer 221a2, and a first upper layer 221a3. The first upper layer 221a3 may be located above the first intermediate layer 221a2, and the first lower layer 221a1 may be located below the first intermediate layer 221a2.

The first intermediate layer 221a2 may include a metal including Ag, Mg, Al, Pt, Pd, Au, Ni, Nd, Ir, Cr, or a compound thereof. Alternatively, the first intermediate layer 221a2 may further include In. For example, the first intermediate layer 221a2 may include Ag and In. In detail, the first intermediate layer 221a2 may include an Ag—In alloy containing In of about 0.4 atomic percentage (at %) or more and about 1 at % or less. However, embodiments according to the present disclosure are not limited thereto.

As the auxiliary pixel electrode 221a of the component area CA has a high light transmittance, the light transmittance of the auxiliary pixel electrode 221a may be increased by adjusting the thickness of the first intermediate layer 221a2. A thickness t1 of the first intermediate layer 221a2 may be about 100 Å or more and about 150 Å or less. When the thickness t1 of the first intermediate layer 221a2 is less than about 100 Å, resistance may be increased as the auxiliary pixel electrode 221a is connected to the auxiliary thin film transistor TFTa via the connection wiring TWL. In contrast, when the thickness t1 of the first intermediate layer 221a2 exceeds about 150 Å, light transmittance may be reduced in the component area CA. Accordingly, when the thickness t1 of the first intermediate layer 221a2 satisfies a range of about 100 Å or more and about 150 Å or less, the resistance is reduced as the auxiliary pixel electrode 221a is connected to the auxiliary thin film transistor TFTa via the connection wiring TWL, thereby increasing the resolution of the auxiliary sub-pixel Pa. Alternatively, as the light transmittance of the auxiliary pixel electrode 221a is improved, the light transmittance in the component area CA may be improved.

The first upper layer 221a3 and the first lower layer 221a1 may each include a transmissive conductive material. For example, the first upper layer 221a3 and the first lower layer 221a1 may each include ITO, IZO, ZnO, In₂O₃, IGO, AZO, or the like. The first upper layer 221a3 may server to narrow a difference in energy level between the auxiliary pixel electrode 221a and a first functional layer 222a. The first lower layer 221a1 may prevent or reduce diffusion of Ag in the first intermediate layer 221a2 thereunder. The thickness of the first lower layer 221a1 may be about 50 Å, and the thickness of the first upper layer 221a3 may be about 100 Å. However, embodiments according to the present disclosure are not limited thereto.

A pixel defining layer 119 may be located on the auxiliary pixel electrode 221a. The pixel defining layer 119 may include an opening 1190P that covers the edge of the auxiliary pixel electrode 221a and overlaps a central portion of each auxiliary pixel electrode 221a. The pixel defining layer 119 may include an organic insulating material, such as polyimide, polyamide, acryl resin, benzocyclobutene, HMDSO, phenol resin, or the like.

The first functional layer 222a and a second functional layer 222c may be arranged on the pixel defining layer 119 and the auxiliary pixel electrode 221a. The first functional layer 222a and the second functional layer 222c may be integrally formed to entire cover the main display area MDA and the component area CA.

The first functional layer 222a may be a single layer or multilayer. For example, when the first functional layer 222a is formed of a polymer material, the first functional layer 222a may include, as a hole transport layer (HTL) that is a single layer structure, poly-(3,4)-ethylene-dihydroxy thiophene (PEDOT) or polyaniline. When the first functional layer 222a is formed of a low molecular weight material, the first functional layer 222a may include a hole injection layer (HIL) and HTL.

The second functional layer 222c may be optional. For example, when the first functional layer 222a and the like is formed of a polymer material, the second functional layer 222c may be located on the first functional layer 222a. The second functional layer 222c may be a single layer or multilayer. The second functional layer 222c may include an electron transport layer (ETL) and/or an electron injection layer (EIL).

An auxiliary emission layer 222ab may be arranged on the first functional layer 222a between the first functional layer 222a and the second functional layer 222c. The auxiliary emission layer 222ab may have a shape patterned to correspond to the auxiliary pixel electrode 221a. The auxiliary emission layer 222ab may include an organic material. The auxiliary emission layer 222ab may include a polymer organic material or low molecular weight organic material that emits light of a certain color.

An auxiliary counter electrode 223a overlapping the auxiliary pixel electrode 221a may be located above the auxiliary emission layer 222ab. The auxiliary counter electrode 223a may be made of a conductive material having a relatively low work function. For example, the auxiliary counter electrode 223a may include a (semi-) transparent layer including Ag, Mg, Al, Ni, Cr, lithium (Li), Ca, an alloy thereof, or the like. Alternatively, the auxiliary counter electrode 223a may further include a layer, such as ITO, IZO, ZnO, or In₂O₃, on the (semi-)transparent layer including the material described above. According to some embodiments, the auxiliary counter electrode 223a may include Ag and Mg.

The auxiliary pixel electrode 221a, the auxiliary emission layer 222ab, and the auxiliary counter electrode 223a, which are sequentially stacked, may form a light-emitting diode, for example, the organic light-emitting diode OLED. The organic light-emitting diode OLED may emit red, green, or blue light, and the light-emitting area of each organic light-emitting diode OLED correspond to a pixel. The auxiliary sub-pixel Pa corresponds to the light-emitting area of the organic light-emitting diode OLED arranged in the component area CA. Before the opening 1190P of the pixel defining layer 119 defines the size and/or width of the light-emitting area, the size and/or width of the auxiliary sub-pixel Pa may be dependent on the opening 1190P of the pixel defining layer 119.

The organic light-emitting diode OLED may be, as described above, covered by the first inorganic encapsulation layer 310, the second inorganic encapsulation layer 330, and the organic encapsulation layer 320 arranged therebetween.

Referring to the transmissive area TA of FIG. 7, the insulating layers on the substrate 100 may each include a hole formed in the transmissive area TA. For example, as illustrated in FIG. 7, the gate insulating layer 112, the first interlayer insulating layer 113, the second interlayer insulating layer 115, the first planarization layer 117, the second planarization layer 118, and the pixel defining layer 119 may include a first hole H1, a second hole H2, a third hole H3, a fourth hole H4, a fifth hole H5, and a sixth hole H6, which are positioned in the transmissive area TA and overlap each other. In this case, the first functional layer 222a may be positioned on the buffer layer 111.

The first functional layer 222a and the second functional layer 222c may cover the transmissive area TA. Furthermore, the auxiliary counter electrode 223a may cover the transmissive area TA. However, embodiments according to the present disclosure are not limited thereto. For example, the auxiliary counter electrode 223a may have an opening formed in the transmissive area TA, and in this case, the light transmittance in the transmissive area TA may be improved.

As described above, the auxiliary pixel electrode 221a in the component area CA may be electrically connected to the auxiliary thin film transistor TFTa in the non-display area NDA, by the connection wiring TWL. In other words, the auxiliary pixel electrode 221a in the component area CA may be electrically connected to the auxiliary pixel circuit PCa in the non-display area NDA, by the connection wiring TWL. The connection wiring TWL may include a multilayer. The connection wiring TWL may have a three-layer structure. The connection wiring TWL may include a second lower layer 221a1′, a second intermediate layer 221a2′, and a second upper layer 221a3′. In this state, the second upper layer 221a3′ may be positioned on the second intermediate layer 221a2′, and the second lower layer 221a1′ may be positioned below the second intermediate layer 221a2′.

When the size of the display panel 10 increases, the distance between the auxiliary pixel circuit PCa in the non-display area NDA and the auxiliary pixel electrode 221a in the component area CA may increase, and thus, the length of the connection wiring TWL connecting the auxiliary pixel circuit PCa with the auxiliary pixel electrode 221a may increase as well. Furthermore, when length of the connection wiring TWL increases, the resistance or the total resistance of the connection wiring TWL may increase, and thus, an IR drop phenomenon and/or a resistive-capacitive (RC) delay phenomenon may occur.

According to some embodiments, the connection wiring TWL may include the second lower layer 221a1′, the second intermediate layer 221a2′, and the second upper layer 221a3′. In this state, the second lower layer 221a1′ and the second upper layer 221a3′ of the connection wiring TWL may include ITO, and the second intermediate layer 221a2′ of the connection wiring TWL may include Ag. Hereinafter, for convenience, the second lower layer 221a1′ and the second upper layer 221a3′ may be referred to as an ITO layer, and the second intermediate layer 221a2′ may be referred to as an Ag layer.

When the connection wiring TWL includes only an ITO layer (about 300 Å), the surface-resistance of the connection wiring TWL may be about 95 Ω/sq. In contrast, when the connection wiring TWL includes an ITO layer (about 50 Å)/an Ag layer (about 100 Å)/an ITO layer (about 100 Å), the surface-resistance of the connection wiring TWL may be about 5.8 Ω/sq. Furthermore, when the connection wiring TWL includes an ITO layer (about 50 Å)/an Ag layer (about 150 Å)/an ITO layer (about 100 Å), the surface-resistance of the connection wiring TWL may be about 3.7 Ω/sq. In other words, compared with a case in which the connection wiring TWL includes an ITO layer only, when the connection wiring TWL includes an ITO layer/an Ag layer/an ITO layer, the surface-resistance of the connection wiring TWL may be reduced. Furthermore, as the thickness of the Ag layer included in the connection wiring TWL increases, the surface-resistance of the connection wiring TWL may be reduced.

However, Ag is a material exhibiting a high reflectivity and a low transmittance compared with ITO, and thus, as the thickness of the Ag layer included in the connection wiring TWL increases, the reflectivity of the connection wiring TWL may increase, and reversely, the light transmittance of the connection wiring TWL may be reduced. Furthermore, the connection wiring TWL is arranged in the component area CA, and when the light transmittance of the connection wiring TWL decreases, the light transmittance of the component area CA in which the connection wiring TWL is arranged may also be reduced.

In other words, as the thickness of the Ag layer included in the connection wiring TWL increases, the surface-resistance of the connection wiring TWL is reduced. However, the reflectivity of the connection wiring TWL may be increased, and the light transmittance of the connection wiring TWL may be reduced. Accordingly, it may be important that the Ag layer in the connection wiring TWL has an appropriate thickness.

Furthermore, when the area of the auxiliary sub-pixel Pa arranged in the component area CA decreases, the light transmittance of the component area CA may be increased, but the lifespan of the auxiliary sub-pixel Pa may be reduced. For example, the lifespan of the functional layer and the emission layer included in the auxiliary sub-pixel Pa may be reduced. In contrast, when the area of the auxiliary sub-pixel Pa arranged in the component area CA increases, the light transmittance of the component area CA may be decreased, but the lifespan of the auxiliary sub-pixel Pa may be increased. For example, the lifespan of the functional layer and the emission layer included in the auxiliary sub-pixel Pa may be increased. In other words, as the area of the auxiliary sub-pixel Pa arranged in the component area CA increases, the lifespan of the auxiliary sub-pixel Pa may be increased, but the light transmittance of the component area CA may be reduced. Accordingly, it may be important that the auxiliary sub-pixel Pa has an appropriate area.

According to some embodiments, a thickness t2 of the Ag layer in the connection wiring TWL, for example, the second intermediate layer 221a2′, may be about 100 Å or more and about 150 Å or less. When the thickness t2 of the Ag layer is less than about 100 Å, the thickness t2 of the Ag layer included in the connection wiring TWL is too small so that the surface-resistance of the connection wiring TWL may be increased, and thus, IR drop may occur. In contrast, when the thickness t2 of the Ag layer exceeds about 150 Å, the thickness t2 of the Ag layer included in the connection wiring TWL is too great so that the light transmittance of the connection wiring TWL may be reduced, and thus, the light transmittance of the component area CA in which the connection wiring TWL is arranged may be reduced. Accordingly, when the thickness t2 of the Ag layer included in the connection wiring TWL satisfies a range of about 100 Å or more and about 150 Å or less, the connection wiring TWL has low surface-resistance so as to prevent or reduce occurrence of IR drop, and the component area CA may be formed or designed at a desired position.

Furthermore, as the connection wiring TWL has a high light transmittance, the component area CA in which the connection wiring TWL is arranged may have a high light transmittance. Accordingly, as the area of the auxiliary sub-pixels Pa arranged in the component area CA may be increased, the lifespan of the auxiliary sub-pixel Pa may be improved.

According to some embodiments, the connection wiring TWL may have the same structure as the auxiliary pixel electrode 221a. The connection wiring TWL and the auxiliary pixel electrode 221a may both have a multilayer. For example, the connection wiring TWL and the auxiliary pixel electrode 221a may both have a three-layer structure. However, embodiments according to the present disclosure are not limited thereto.

According to some embodiments, the connection wiring TWL may include the same material as the material forming the auxiliary pixel electrode 221a. In detail, the second lower layer 221a1′, the second intermediate layer 221a2′, and the second upper layer 221a3′ of the connection wiring TWL may include the same material as the first lower layer 221a1, the first intermediate layer 221a2, and the first upper layer 221a3 of the auxiliary pixel electrode 221a.

According to some embodiments, the connection wiring TWL may be integrally formed with the auxiliary pixel electrode 221a. In detail, the second lower layer 221a1′, the second intermediate layer 221a2′, and the second upper layer 221a3′ of the connection wiring TWL may be respectively integrally formed with the first lower layer 221a1, the first intermediate layer 221a2, and the first upper layer 221a3 of the auxiliary pixel electrode 221a. Furthermore, the connection wiring TWL may be arranged in the same layer as the auxiliary pixel electrode 221a. The connection wiring TWL and the auxiliary pixel electrode 221a may be continuously formed in the same plane without passing through a contact hole.

According to some embodiments, the connection wiring TWL and the auxiliary pixel electrode 221a having the same structure may mean that the connection wiring TWL and the auxiliary pixel electrode 221a are formed by the same process. Accordingly, as the connection wiring TWL and the auxiliary pixel electrode 221a may be simultaneously formed by the same process, the manufacturing efficiency of a display apparatus may be remarkably increased.

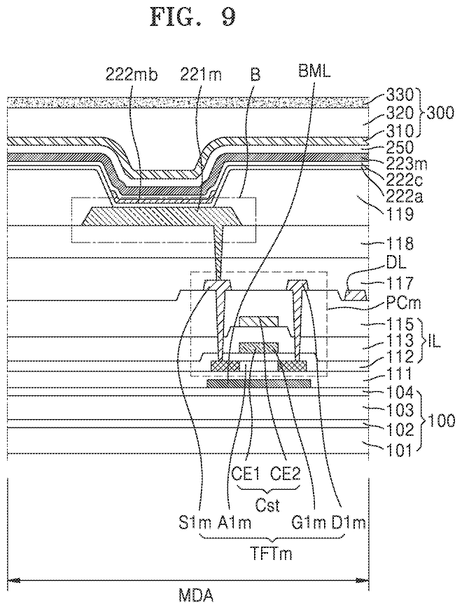

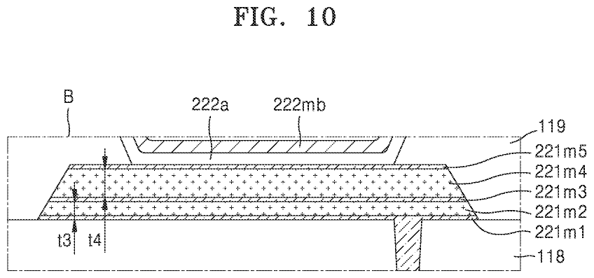

FIG. 9 is a schematic cross-sectional view of a partial area of a display apparatus according to one or more embodiments. FIG. 10 is a schematic cross-sectional view of a region B of FIG. 9. FIG. 9 illustrates a part of the main display area MDA.

Although, in FIG. 7, the auxiliary pixel electrode 221a positioned in the component area CA and the pixel circuit PCa positioned in the non-display area NDA are described, this may be applied to the main pixel circuit PCm and a main pixel electrode 221m positioned in the main display area MDA. In other words, the main thin film transistor TFTm of the main pixel circuit PCm positioned in the main display area MDA may have the same/similar structure as/to the auxiliary thin film transistor TFTa of the auxiliary pixel circuit PCa positioned in the non-display area NDA, and the main pixel electrode 221m positioned in the main display area MDA may be partially the same as the structure of the auxiliary pixel electrode 221a of the component area CA. However, the main pixel electrode 221m may be positioned above the main pixel circuit PCm, and may be electrically connected to the main pixel circuit PCm positioned thereunder.

Referring to FIG. 9, a main thin film transistor TFTa may be located on the substrate 100. The main thin film transistor TFTm may serve as the main pixel circuit PCm. Planarization layers 118 and 119 may be located on the main thin film transistor TFTm. The main pixel electrode 221m may be located on the planarization layers 118 and 119, and functional layers 222a and 222c, a main emission layer 222mb, a main counter electrode 223m, and the thin film encapsulation layer 300 may be located the main pixel electrode 221m.

According to some embodiments, the main pixel electrode 221m may include a multilayer. The main pixel electrode 221m may have a five-layer structure. The main pixel electrode 221m may include a third lower layer 221m1, a third intermediate layer 221m2, a fifth intermediate layer 221m3, a fourth intermediate layer 221m4, and a third upper layer 221m5. In this state, the third intermediate layer 221m2 may be located on the third lower layer 221m1, the fifth intermediate layer 221m3 may be located on the third intermediate layer 221m2, the fourth intermediate layer 221m4 may be located on the fifth intermediate layer 221m3, and the third upper layer 221m5 may be located on the fourth intermediate layer 221m4. In other words, the third lower layer 221m1 may be the lowermost layer of the main pixel electrode 221m, the third upper layer 221m5 may be the uppermost layer of the main pixel electrode 221m, and the third lower layer 221m1, the third intermediate layer 221m2, the fifth intermediate layer 221m3, the fourth intermediate layer 221m4, and the third upper layer 221m5 may be sequentially arranged in the thickness direction of the substrate 100.

According to some embodiments, the third intermediate layer 221m2 and the fourth intermediate layer 221m4 may include the same material as the second intermediate layer 221a2′, and the third lower layer 221m1, the fifth intermediate layer 221m3, and the third upper layer 221m5 may include the same material as the second lower layer 221a1′. For example, the third intermediate layer 221m2 and the fourth intermediate layer 221m4 may be layers including Ag, and the third lower layer 221m1, the fifth intermediate layer 221m3, and the third upper layer 221m5 may be layers including ITO. Furthermore, the third intermediate layer 221m2 and the fourth intermediate layer 221m4 may each include an Ag—In alloy containing In of about 0.4 at % or more and about 1 at % or less. However, embodiments according to the present disclosure are not limited thereto.

Light emitted from the main emission layer 222mb may travel toward the main counter electrode 223m. However, part of the light emitted from the main emission layer 222mb may travel toward the main pixel electrode 221m. Furthermore, the light reflected from the main counter electrode 223m may travel toward the main pixel electrode 221m. Accordingly, the main pixel electrode 221m may have high reflectivity.

As described above, as the thickness of the Ag layer increases, the reflectivity of the electrode including the Ag layer increases, by increasing the thickness of the Ag layer included in the main pixel electrode 221m, the main pixel electrode 221m may have high reflectivity.

According to some embodiments, a thickness t4 of the fourth intermediate layer 221m4 of the main pixel electrode 221m may be in a range of about 800 Å or more and about 1000 Å or less. When the thickness t4 of the fourth intermediate layer 221m4 of the main pixel electrode 221m is less than about 800 Å, the reflectivity of the main pixel electrode 221m may be too low. In contrast, when the thickness t4 of the fourth intermediate layer 221m4 of the main pixel electrode 221m exceeds about 1,000 Å, a too large amount of Ag is unnecessarily needed so that the manufacturing cost of a display apparatus may be raised. Accordingly, when the thickness t4 of the fourth intermediate layer 221m4 of the main pixel electrode 221m satisfies a range of about 800 Å or more and about 1000 Å or less, the manufacturing cost of a display apparatus may be reduced and the main pixel electrode 221m may have reflectivity of a desired level.

According to some embodiments, the thickness t4 of the fourth intermediate layer 221m4 of the main pixel electrode 221m may be greater than a thickness t3 of the third intermediate layer 221m2 of the main pixel electrode 221m. For example, the thickness t3 of the third intermediate layer 221m2 of the main pixel electrode 221m may be in a range of about 100 Å or more and about 150 Å or less.

Furthermore, the thickness t3 of the third intermediate layer 221m2 of the main pixel electrode 221m may be the same as the thickness t1 of the first intermediate layer 221a2 of the auxiliary pixel electrode 221a and the thickness t2 of the second intermediate layer 221a2′ of the connection wiring TWL.

The thickness of the third lower layer 221m1 may be about 50 Å, and the thickness of the third upper layer 221m5 may be about 70 Å. Furthermore, the thickness of the fifth intermediate layer 221m3 may be about 100 Å. However, embodiments according to the present disclosure are not limited thereto.

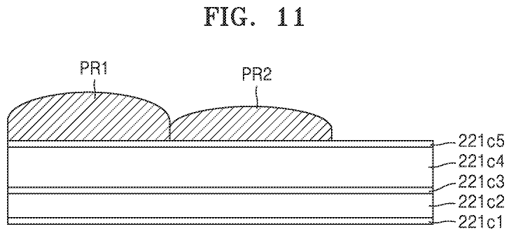

FIGS. 11 to 14 are schematic cross-sectional views showing a method of manufacturing the main pixel electrode 221m and the auxiliary pixel electrode 221a, according to one or more embodiments.

First, as illustrated in FIG. 11, a first transmissive conductive material layer 221c1, a first metal layer 221c2, a second transmissive conductive material layer 221c3, a second metal layer 221c4, and a third transmissive conductive material layer 221c5 may be sequentially arranged in the thickness direction of the substrate 100. The first transmissive conductive material layer 221c1, the second transmissive conductive material layer 221c3, and the third transmissive conductive material layer 221c5 may each include ITO, IZO, ZnO, In₂O₃, IGO, AZO, or the like. Furthermore, the first metal layer 221c2 and the second metal layer 221c4 may each include a metal including Ag, Mg, Al, Pt, Pd, Au, Ni, Nd, Ir, Cr, or a compound thereof.

According to some embodiments, a first photoresist PR1 and a second photoresist PR2 may be located on the third transmissive conductive material layer 221c5 that is positioned at the top layer. The first photoresist PR1 and the second photoresist PR2 may cover a portion in which the main pixel electrode 221m and the auxiliary pixel electrode 221a are to be formed. The first photoresist PR1 may be thicker than the second photoresist PR2. The first photoresist PR1 may be positioned in a portion in which the main pixel electrode 221m is to be formed, and the second photoresist PR2 may be positioned in a portion in which the auxiliary pixel electrode 221a is to be formed.

According to some embodiments, the first photoresist PR1 and the second photoresist PR2 having different thicknesses may be simultaneously formed. For example, after a photoresist material is located on the third transmissive conductive material layer 221c5 positioned at the top layer, light of different light amounts are irradiated onto area in which the first photoresist PR1 and the second photoresist PR2 are to be formed, by using a half tone mask, to develop the photoresist material and remove a part thereof, the first photoresist PR1 and the second photoresist PR2 having different thicknesses may be simultaneously formed.

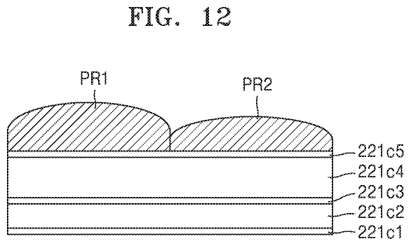

Referring to FIG. 12, by performing etching by a method, such as wet etching and the like as described above, the first transmissive conductive material layer 221c1, the first metal layer 221c2, the second transmissive conductive material layer 221c3, the second metal layer 221c4, and the third transmissive conductive material layer 221c5, in which photoresist is not arranged in FIG. 11, may be removed. A display panel may be patterned as a whole by removing, by a method, such as wet etching, the first transmissive conductive material layer 221c1, the first metal layer 221c2, the second transmissive conductive material layer 221c3, the second metal layer 221c4, and the third transmissive conductive material layer 221c5, which are positioned in a portion in which the main pixel electrode 221m and the auxiliary pixel electrode 221a are not to be formed.

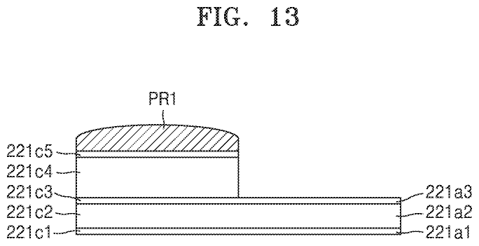

Referring to FIG. 13, the second photoresist PR2 on the third transmissive conductive material layer 221c5 in the portion in which the auxiliary pixel electrode 221a is to be formed, may be removed by a dry etching method. Simultaneously, the first photoresist PR1 on the third transmissive conductive material layer 221c5 in the portion in which the main pixel electrode 221m is to be formed, may be partially removed. As the first photoresist PR1 is thicker than the second photoresist PR2, although the thickness of the first photoresist PR1 is decreased during the dry etching, the first photoresist PR1 may still be positioned in the portion in which the main pixel electrode 221m is to be formed.

After the second photoresist PR2 is removed, the second metal layer 221c4 and the third transmissive conductive material layer 221c5, which are positioned in a portion in which the second photoresist PR2 is removed, may be removed through etching, for example, wet etching. Removing the second metal layer 221c4 and the third transmissive conductive material layer 221c5, which are positioned in the portion in which the second photoresist PR2 is removed, through etching, and maintaining the first transmissive conductive material layer 221c1, the first metal layer 221c2, and the second transmissive conductive material layer 221c3, may be achieved by using a difference between an etch rate of the second metal layer 221c4 and the third transmissive conductive material layer 221c5, and an etch rate of the first transmissive conductive material layer 221c1, the first metal layer 221c2, and the second transmissive conductive material layer 221c3. Alternatively, removing the second metal layer 221c4 and the third transmissive conductive material layer 221c5, which are positioned in the portion in which the second photoresist PR2 is removed, through etching, and maintaining the first transmissive conductive material layer 221c1, the first metal layer 221c2, and the second transmissive conductive material layer 221c3, may be achieved by using an etch rate of the second metal layer 221c4 and an etch rate of the second transmissive conductive material layer 221c3. However, embodiments according to the present disclosure are not limited thereto.

For example, after the second metal layer 221c4 having a relatively high etch rate is etched and removed by setting the etch rate of the second metal layer 221c4 to be greater than the etch rate of the second transmissive conductive material layer 221c3, an etching process is set to be terminated before the second transmissive conductive material layer 221c3 having a relatively low etch rate is completely etched away (or before being etched), the second metal layer 221c4 and the third transmissive conductive material layer 221c5, which are not covered by the second photoresist PR2, may be removed, and the first transmissive conductive material layer 221c1, the first metal layer 221c2, and the second transmissive conductive material layer 221c3 may be maintained. Prior to the etching of the second metal layer 221c4, the third transmissive conductive material layer 221c5 may be etched.

According to some embodiments, as the second metal layer 221c4 and the third transmissive conductive material layer 221c5 covered by the second photoresist PR2 are removed, the auxiliary pixel electrode 221a may be formed. The auxiliary pixel electrode 221a may be a multilayer. The auxiliary pixel electrode 221a may include three layers. The auxiliary pixel electrode 221a may include the first transmissive conductive material layer 221c1, the first metal layer 221c2, and the second transmissive conductive material layer 221c3, which are not selectively etched. In other words, the first transmissive conductive material layer 221c1, the first metal layer 221c2, and the second transmissive conductive material layer 221c3, which are not etched, may be respectively the first lower layer 221a1, the first intermediate layer 221a2, and the first upper layer 221a3 of the auxiliary pixel electrode 221a. In other words, the auxiliary pixel electrode 221a may include the first lower layer 221a1, the first intermediate layer 221a2, and the first upper layer 221a3.

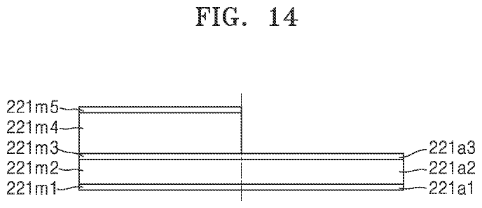

Referring to FIG. 14, the first photoresist PR1 may be removed. After the first photoresist PR1 is removed, the first transmissive conductive material layer 221c1, the first metal layer 221c2, the second transmissive conductive material layer 221c3, the second metal layer 221c4, and the third transmissive conductive material layer 221c5 may be positioned in the portion covered by the first photoresist PR1. The first transmissive conductive material layer 221c1, the first metal layer 221c2, the second transmissive conductive material layer 221c3, the second metal layer 221c4, and the third transmissive conductive material layer 221c5 in the portion covered by the first photoresist PR1 may respectively become the third lower layer 221m1, the third intermediate layer 221m2, the fifth intermediate layer 221m3, the fourth intermediate layer 221m4, and the third upper layer 221m5 of the main pixel electrode 221m. The main pixel electrode 221m may include five layers. The main pixel electrode 221m may include the third lower layer 221m1, the third intermediate layer 221m2, the fifth intermediate layer 221m3, the fourth intermediate layer 221m4, and the third upper layer 221m5. Although, in FIGS. 11 and 14, a process of forming the main pixel electrode 221m of the main display area MDA and the auxiliary pixel electrode 221a of the component area CA is described, as the connection wiring TWL and the auxiliary pixel electrode 221a are formed in the same layer and in the same structure, the connection wiring TWL may also be formed by the same process as the auxiliary pixel electrode 221a.

According to some embodiments, the main pixel electrode 221m of the main display area MDA, the auxiliary pixel electrode 221a of the component area CA, and the connection wiring TWL may be formed by using one mask. Accordingly, the number of masks used in the method of manufacturing a display apparatus may be reduced.

According to the related art, when a complete reflective pixel electrode of the main display area MDA is applied to the component area CA in the same manner, it is difficult to secure the light transmittance of the component area CA. For example, it is difficult to increase the light transmittance of the component area CA. To secure the light transmittance of the component area CA, the connection wiring TWL arranged in the component area CA is formed as an ITO layer, but when the connection wiring TWL includes an ITO layer, the connection wiring TWL may have high surface-resistance, and a process time may be increased because an additional process to form the connection wiring TWL including an ITO layer is performed.

According to some embodiments, as the pixel electrodes of the main display area MDA and the component area CA have different structures, the light transmittance of the component area CA may be secured, and the pixel electrode and the connection wiring TWL arranged in the component area CA may have the same structure and include the same material, thereby reducing the resistance of the connection wiring TWL and the manufacturing time of manufacturing a display apparatus.

According to some embodiments as described above, a display panel in which, in the component area, the transmittance of an auxiliary pixel electrode may be relatively high and the resistance of a connection wiring may be relatively low, and a display apparatus including the same, may be implemented. The scope of embodiments according to the present disclosure are not limited by the effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
a substrate including a main display area, a component area, and a non-display area;
a main pixel electrode in the main display area of the substrate and including a multilayer;
a main thin film transistor in the main display area of the substrate and electrically connected to the main pixel electrode;
an auxiliary pixel electrode in the component area of the substrate and including a multilayer;
an auxiliary thin film transistor in the non-display area of the substrate; and
a connection wiring electrically connecting the auxiliary thin film transistor to the auxiliary pixel electrode and having a same structure as the auxiliary pixel.

2. The display panel of claim 1, wherein the connection wiring includes a same material as a material forming the auxiliary pixel electrode.

3. The display panel of claim 2, wherein the auxiliary pixel electrode includes a first lower layer, a first intermediate layer on the first lower layer, and a first upper layer on the first intermediate layer.

4. The display panel of claim 3, wherein a thickness of the first intermediate layer of the auxiliary pixel electrode is 100 Å or more and 50 Å or less.

5. The display panel of claim 3, wherein the first upper layer and the first lower layer of the auxiliary pixel electrode include ITO, IZO, AZO, or GZO, and the first intermediate layer of the auxiliary pixel electrode includes Ag.

6. The display panel of claim 5, wherein the first intermediate layer of the auxiliary pixel electrode includes In of 0.4 at % or more and 1 at % or less.

7. The display panel of claim 3, wherein the connection wiring includes a second lower layer, a second intermediate layer on the second lower layer, and a second upper layer on the second intermediate layer.

8. The display panel of claim 7, wherein the second intermediate layer of the connection wiring has a same thickness as the first intermediate layer of the auxiliary pixel electrode.

9. The display panel of claim 7, wherein the second intermediate layer of the connection wiring includes a same material as the first intermediate layer of the auxiliary pixel electrode.

10. The display panel of claim 7, wherein the second intermediate layer of the connection wiring is integrally formed with the first intermediate layer of the auxiliary pixel electrode.

11. The display panel of claim 7, wherein each of the second lower layer and the second upper layer of the connection wiring includes a same material as the first lower layer and the first upper layer of the auxiliary pixel electrode.

12. The display panel of claim 7, wherein the second lower layer and the second upper layer of the connection wiring are integrally formed with the first lower layer and the first upper layer of the auxiliary pixel electrode, respectively.

13. The display panel of claim 7, wherein the main pixel electrode includes a third intermediate layer and a fourth intermediate layer.

14. The display panel of claim 13, wherein the main pixel electrode includes a third lower layer below the third intermediate layer, a fifth intermediate layer between the third intermediate layer and the fourth intermediate layer, and a third upper layer on fourth intermediate layer.

15. The display panel of claim 13, wherein a thickness of the fourth intermediate layer of the main pixel electrode is greater than a thickness of the third intermediate layer.

16. The display panel of claim 13, wherein the third intermediate layer of the main pixel electrode has a same thickness as the first intermediate layer of the auxiliary pixel electrode.

17. The display panel of claim 13, wherein a thickness of the fourth intermediate layer is 800 Å or more and 1000 Å or less.

18. A display apparatus comprising:
a display panel; and
an electronic element below the display panel,
wherein the display panel comprises:
a substrate includes a main display area, a component area, and a non-display area;
a main pixel electrode in the main display area of the substrate and including a multilayer;
a main thin film transistor in the main display area of the substrate and electrically connected to the main pixel electrode;
an auxiliary pixel electrode in the component area of the substrate and including a multilayer;
an auxiliary thin film transistor in the non-display area of the substrate; and
a connection wiring electrically connecting the auxiliary thin film transistor to the auxiliary pixel electrode and having a same structure as the auxiliary pixel.

19. The display apparatus of claim 18, wherein the auxiliary pixel electrode includes a first lower layer, a first intermediate layer on the first lower layer, and a first upper layer on the first intermediate layer, and
the connection wiring includes a second lower layer, a second intermediate layer on the second lower layer, and a second upper layer on the second intermediate layer.

20. The display apparatus of claim 19, wherein the second intermediate layer of the connection wiring has a same thickness as the first intermediate layer of the auxiliary pixel electrode, and the second intermediate layer of the connection wiring is integrally formed with the first intermediate layer of the auxiliary pixel electrode.
